(19) United States
(12) Patent Application Publication
(10) Pub. No.: US 2025/0344408 A1
(43) Pub. Date: Nov. 6, 2025

(54) RESISTIVE RANDOM ACCESS MEMORY DEVICE AND FABRICATION METHOD THEREOF

(71) Applicant: UNITED MICROELECTRONICS CORP., Hsin-Chu City (TW)

(72) Inventors: Shu-Hung Yu, Kaohsiung City (TW); Chiun-Yi Wu, Tainan City (TW); Chun-Chia Chen, Tainan City (TW); Chuan-Fu Wang, Miaoli County (TW)

(73) Assignee: UNITED MICROELECTRONICS CORP., Hsin-Chu City (TW)

(21) Appl. No.: 18/740,556

(22) Filed: Jun. 12, 2024

(30) Foreign Application Priority Data
May 2, 2024 (TW) 113116346

(51) Int. Cl. H10B 63/00

(52) U.S. Cl. CPC H10B 63/80

(57) ABSTRACT

A resistive random access memory device includes a substrate; a first inter-layer dielectric (ILD) layer disposed on the substrate; a first interconnect structure disposed in the first ILD layer; a capping layer disposed on the first interconnect structure and the first ILD layer; an intermediate dielectric layer disposed on the capping layer; a conductive via disposed in the capping layer and the intermediate dielectric layer, wherein the conductive via comprises a polishing stop layer, a barrier layer on the polishing stop layer, and a tungsten layer on the barrier layer; and a resistive switching structure disposed on the conductive via.

### BACKGROUND OF THE INVENTION

### 1. Field of the Invention

The present invention relates to the field of semiconductor technology, and in particular to a resistive random access memory (RRAM) device and a manufacturing method thereof.

### 2. Description of the Prior Art

Resistive random access memory (RRAM) is a memory structure including an array of RRAM cells each of which stores a bit of data using resistance values, rather than electronic charge. Particularly, each RRAM cell includes a resistive-switching material layer, the resistance of which can be adjusted to represent logic “0” or logic “1.”

In advanced technology nodes, the feature size scales down and the size of memory devices is reduced accordingly. However, the reduction of the RRAM devices is limited due to the “forming” operation. In the “forming” process, a high voltage is applied to the RRAM device to generate a conductive path in the resistive-switching material layer.

When integrating RRAM devices into the 12 nm node process, a short via design is typically used. Since the tungsten metal grinding process consumes more silicon oxide layers, the step height required for alignment in the lithography process is not enough. Although an additional photomask can solve the alignment problem, the cost of the process is increased.

### SUMMARY OF THE INVENTION

It is one object of the present invention to provide an improved resistive random access memory (RRAM) device and a manufacturing method thereof to solve the deficiencies or shortcomings of the existing technology.

One aspect of the invention provides a resistive random access memory device including a substrate; a first inter-layer dielectric (ILD) layer disposed on the substrate; a first interconnect structure disposed in the first ILD layer; a capping layer disposed on the first interconnect structure and the first ILD layer; an intermediate dielectric layer disposed on the capping layer; a conductive via disposed in the capping layer and the intermediate dielectric layer, wherein the conductive via comprises a polishing stop layer, a barrier layer on the polishing stop layer, and a tungsten layer on the barrier layer; and a resistive switching structure disposed on the conductive via.

According to some embodiments, the conductive via comprises an upper portion protruding from a top surface of the intermediate dielectric layer.

According to some embodiments, the resistive random access memory device further includes a sidewall spacer disposed around the upper portion of the conductive via and the resistive switching structure.

According to some embodiments, the sidewall spacer covers a sidewall of the resistive switching structure, a sidewall of the upper portion of the conductive via, and the top surface of the intermediate dielectric layer, and wherein the sidewall spacer is in direct contact with the polishing stop layer.

According to some embodiments, the sidewall spacer layer comprises a silicon nitride layer and a silicon oxide layer.

According to some embodiments, the capping layer comprises a nitrogen-doped silicon carbide (NDC) layer

According to some embodiments, the intermediate dielectric layer comprises a TEOS-based silicon oxide layer.

According to some embodiments, the polishing stop layer comprises tantalum nitride.

According to some embodiments, the barrier layer comprises titanium nitride.

According to some embodiments, the resistive random access memory device further includes a second inter-layer dielectric (ILD) layer covering the sidewall spacer; and a second interconnect structure disposed in the second ILD layer.

Another aspect of the invention provides a method for forming a resistive random access memory device. A substrate is provided. A first inter-layer dielectric (ILD) layer is formed on the substrate. A first interconnect structure is formed in the first ILD layer. A capping layer is formed on the first interconnect structure and the first ILD layer. An intermediate dielectric layer is formed on the capping layer. A conductive via is formed in the capping layer and the intermediate dielectric layer, wherein the conductive via comprises a polishing stop layer, a barrier layer on the polishing stop layer, and a tungsten layer on the barrier layer. A resistive switching structure is formed on the conductive via.

According to some embodiments, the conductive via comprises an upper portion protruding from a top surface of the intermediate dielectric layer.

According to some embodiments, the method further includes the step of forming a sidewall spacer around the upper portion of the conductive via and the resistive switching structure.

According to some embodiments, the sidewall spacer covers a sidewall of the resistive switching structure, a sidewall of the upper portion of the conductive via, and the top surface of the intermediate dielectric layer, and wherein the sidewall spacer is in direct contact with the polishing stop layer.

According to some embodiments, the sidewall spacer layer comprises a silicon nitride layer and a silicon oxide layer.

According to some embodiments, the capping layer comprises a nitrogen-doped silicon carbide (NDC) layer

According to some embodiments, the intermediate dielectric layer comprises a TEOS-based silicon oxide layer.

According to some embodiments, the polishing stop layer comprises tantalum nitride.

According to some embodiments, the barrier layer comprises titanium nitride.

According to some embodiments, the method further includes the steps of forming a second inter-layer dielectric (ILD) layer on the sidewall spacer; and forming a second interconnect structure in the second ILD layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic cross-sectional view of a partial memory device area of a resistive random access memory device according to an embodiment of the present invention.

FIG. 2 to FIG. 5 are schematic diagrams showing a method of forming a RRAM device according to an embodiment of the present invention.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized, and structural, logical, and electrical changes may be made without departing from the scope of the present invention. Therefore, the following detailed description is not to be considered as limiting, but the embodiments included herein are defined by the scope of the accompanying claims.

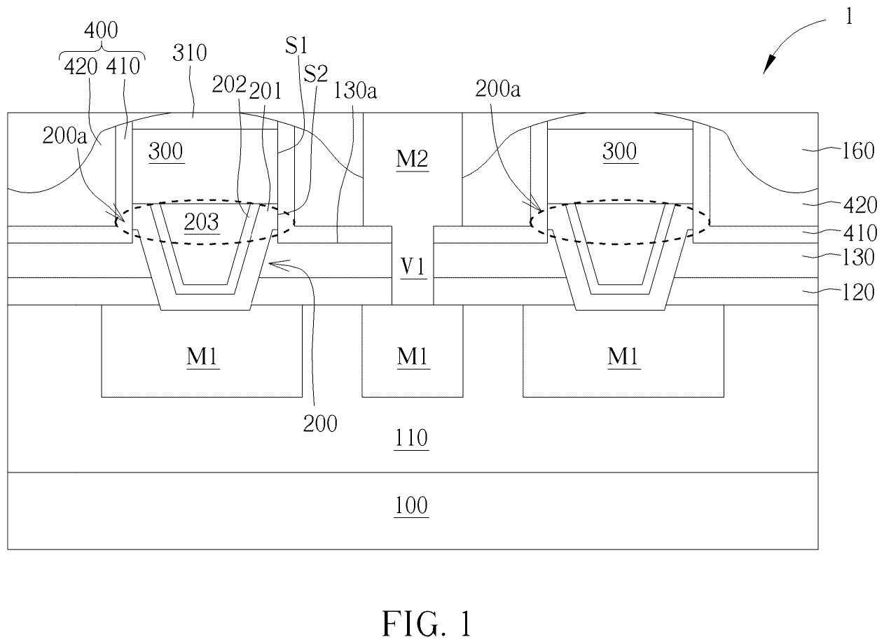

Please refer to FIG. 1, which is a schematic cross-sectional view of a partial memory device region of a resistive random access memory (RRAM) device according to an embodiment of the present invention. As shown in FIG. 1, the RRAM device 1 includes a substrate 100 and a first interlayer dielectric layer 110 disposed on the substrate 100. According to an embodiment of the present invention, the substrate 100 may be a semiconductor substrate, such as a silicon substrate, but is not limited thereto. According to an embodiment of the present invention, for example, the first interlayer dielectric layer 110 may include a low dielectric constant material layer or an ultra-low dielectric constant material layer. According to an embodiment of the present invention, the thickness of the first interlayer dielectric layer 110 may be, for example, about 800-900 angstroms.

According to an embodiment of the present invention, a first interconnect structure M1 is formed in the first interlayer dielectric layer 110. According to an embodiment of the present invention, for example, the first interconnect structure M1 may be a copper damascene structure. According to an embodiment of the present invention, a capping layer 120 is formed on the first interconnect structure M1 and the first interlayer dielectric layer 110. According to an embodiment of the present invention, for example, the capping layer 120 includes a nitrogen-doped silicon carbide layer, but is not limited thereto. According to an embodiment of the present invention, the thickness of the capping layer 120 may be about 100 angstroms, for example.

According to an embodiment of the present invention, an intermediate dielectric layer 130 is formed on the capping layer 120. According to an embodiment of the present invention, for example, the intermediate dielectric layer 130 may include a TEOS-based silicon oxide layer, but is not limited thereto. According to an embodiment of the present invention, the thickness of the intermediate dielectric layer 130 may be about 100 angstroms, for example.

According to an embodiment of the present invention, the RRAM device 1 further includes a conductive via 200 disposed in the capping layer 120 and the intermediate dielectric layer 130. According to an embodiment of the present invention, for example, the conductive via 200 includes an outermost polishing stop layer 201, a barrier layer 202 located on the polishing stop layer 201, and a tungsten layer 203 located on the barrier layer 202. According to an embodiment of the present invention, the polishing stop layer 201 may include, for example, tantalum nitride or other materials that have a high polishing selectivity relative to the tungsten layer 203. According to an embodiment of the present invention, the barrier layer 202 may include, for example, titanium nitride, but is not limited thereto.

According to an embodiment of the present invention, the height of the conductive via 200 may be approximately between 200-600 angstroms, for example, between 400-500 angstroms. According to an embodiment of the present invention, the conductive via 200 includes an upper portion 200a protruding from the top surface 130a of the intermediate dielectric layer 130. The RRAM device 1 further includes a resistive switching structure 300 disposed on the conductive via 200. According to an embodiment of the present invention, the sidewall S1 of the resistive switching structure 300 may be flush with the sidewall S2 of the upper portion 200a of the conductive via 200. According to an embodiment of the present invention, the top surface of the resistive switching structure 300 may be covered by the hard mask layer 310.

According to an embodiment of the present invention, the resistive switching structure 300 may include a stacked structure composed of a bottom electrode layer, a resistive switching layer, and a top electrode layer. For example, the bottom electrode layer may include TaN, TiN, Pt, Ir, Ru, or W, the resistive switching layer may include hafnium oxide, tantalum oxide, titanium, titanium oxide, or combinations thereof, and the top electrode layer may include TiN, TaN, Pt, Ir, or W, but not limited thereto.

According to an embodiment of the present invention, a sidewall spacer 400 is provided around the upper portion 200a of the conductive via 200 and the resistive switching structure 300. According to an embodiment of the present invention, for example, the sidewall spacer 400 may include a silicon nitride layer 410 and a silicon oxide layer 420, but is not limited thereto. According to an embodiment of the present invention, the silicon nitride layer 410 conformally covers the sidewall S1 of the resistive switching structure 300, the sidewall S2 of the upper portion 200a of the conductive via 200, and the top surface 130a of the intermediate dielectric layer 130. According to an embodiment of the present invention, the silicon nitride layer 410 directly contacts the polishing stop layer 201 but does not directly contact the barrier layer 202 and the tungsten layer 203.

According to an embodiment of the present invention, the RRAM device 1 further includes a second interlayer dielectric layer 160 covering the sidewall spacer 400 and the resistive switching structure 300. According to an embodiment of the present invention, a second interconnect structure M2 may be formed in the second interlayer dielectric layer 160. According to an embodiment of the present invention, for example, the second interconnect structure M2 may be disposed between two adjacent resistive switching structures 300. The second interconnect structure M2 may be electrically connected to the first interconnect structure M1 through the conductive via V1.

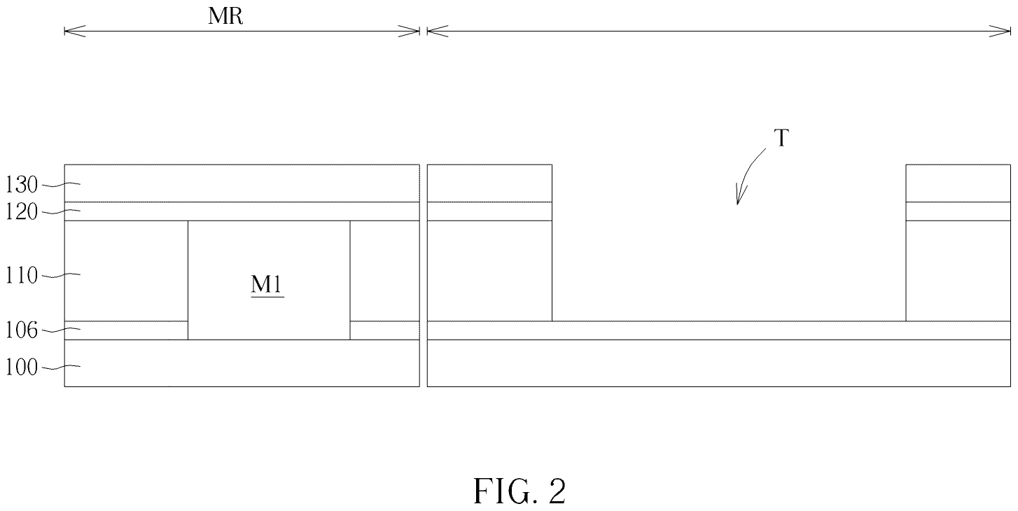

Please refer to FIG. 2 to FIG. 5, which are schematic diagrams showing a method of forming a resistive random access memory device according to an embodiment of the present invention, in which like layers, materials or regions are designated by like numeral numbers or labels. As shown in FIG. 2, a substrate 100 is provided, for example, a silicon substrate. According to an embodiment of the present invention, the substrate 100 includes a memory cell region MR and an alignment mark region AM. According to an embodiment of the present invention, an etching stop layer 106, a first interlayer dielectric layer 110, a capping layer 120, and an intermediate dielectric layer 130 are formed on the substrate 100.

For example, the etching stop layer 106 may comprise a nitrogen-doped silicon carbide layer, but is not limited thereto. The first interlayer dielectric layer 110 may comprise a low dielectric constant material layer or an ultra-low dielectric constant material layer. According to an embodiment of the present invention, the thickness of the first interlayer dielectric layer 110 may be about 800-900 angstroms, for example. According to an embodiment of the present invention, for example, the capping layer 120 may comprise a nitrogen-doped silicon carbide layer, but is not limited thereto. According to an embodiment of the present invention, the thickness of the capping layer 120 may be about 100 angstroms, for example. According to an embodiment of the present invention, for example, the intermediate dielectric layer 130 may include a TEOS-based silicon oxide layer, but is not limited thereto. According to an embodiment of the present invention, the thickness of the intermediate dielectric layer 130 may be about 300 angstroms, for example.

According to an embodiment of the present invention, a first interconnect structure M1 is formed in the first interlayer dielectric layer 110 in the memory cell region MR. According to an embodiment of the present invention, for example, the first interconnect structure M1 may be a copper damascene structure. According to an embodiment of the present invention, an alignment trench T is formed in the alignment mark region AM using a photolithography process and an etching process. According to an embodiment of the present invention, the alignment trench T may be recessed into the first interlayer dielectric layer 110, and the bottom of the alignment trench T may expose the etching stop layer 106. For example, the depth of the alignment trench T is approximately 1200-1300 angstroms.

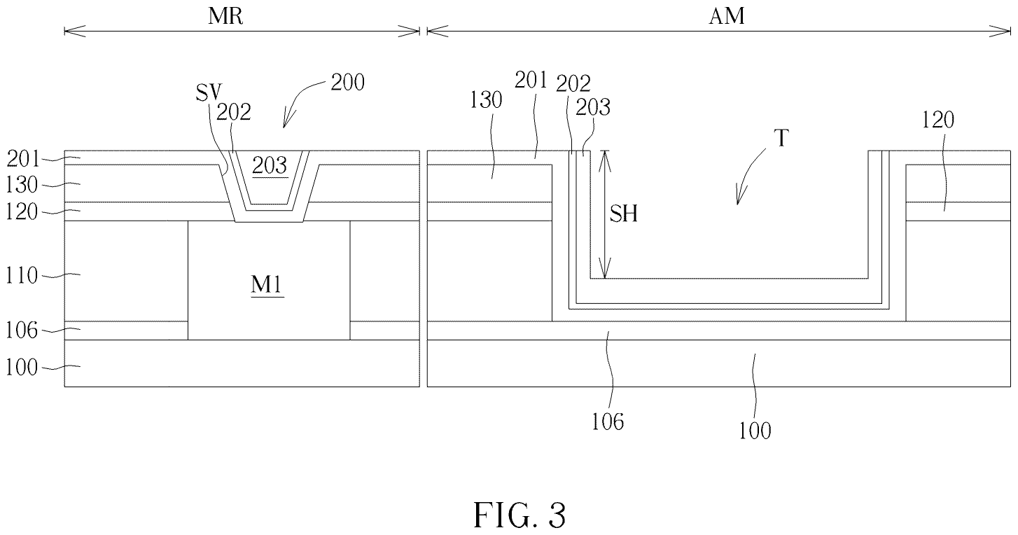

As shown in FIG. 3, a photolithography process and an etching process are then performed to form a via hole SV in the intermediate dielectric layer 130 and the capping layer 120 above the first interconnect structure M1 in the memory cell region MR, exposing part of the first interconnect structure M1. A chemical vapor deposition (CVD) process is then performed to deposit a polishing stop layer 201, a barrier layer 202 and a tungsten layer 203 on the substrate 100 in a blanket manner. The polishing stop layer 201 and the barrier layer 202 are conformally filled into the via hole SV. The remaining space in the via hole SV is then filled by the tungsten layer 203. In the alignment mark region AM, the polishing stop layer 201, the barrier layer 202 and the tungsten layer 203 are conformally filled into the alignment trench T.

Subsequently, a tungsten chemical mechanical polishing (WCMP) process is performed to polish away the barrier layer 202 and the tungsten layer 203 above the polishing stop layer 201 from the memory cell region MR and the alignment mark region AM. Since the polishing stop layer 201 has a high selectivity relative to the tungsten layer 203, the polishing will stop on the polishing stop layer 201, leaving the barrier layer 202 and the tungsten layer 203 in the via hole SV to form the conductive via 200. At this point, there will also be residual barrier layer 202 and tungsten layer 203 in the alignment trench T. Because of the polishing stop layer 201, the thickness of the intermediate dielectric layer 130 in the alignment mark region AM and the thickness of the intermediate dielectric layer 130 in the memory cell region MR can be approximately the same, so the intermediate dielectric layer 130 is not consumed in the WCMP process, so that the trench step height SH in the alignment mark region AM can reach about 920 angstroms, which improves the alignment accuracy of the subsequent lithography process.

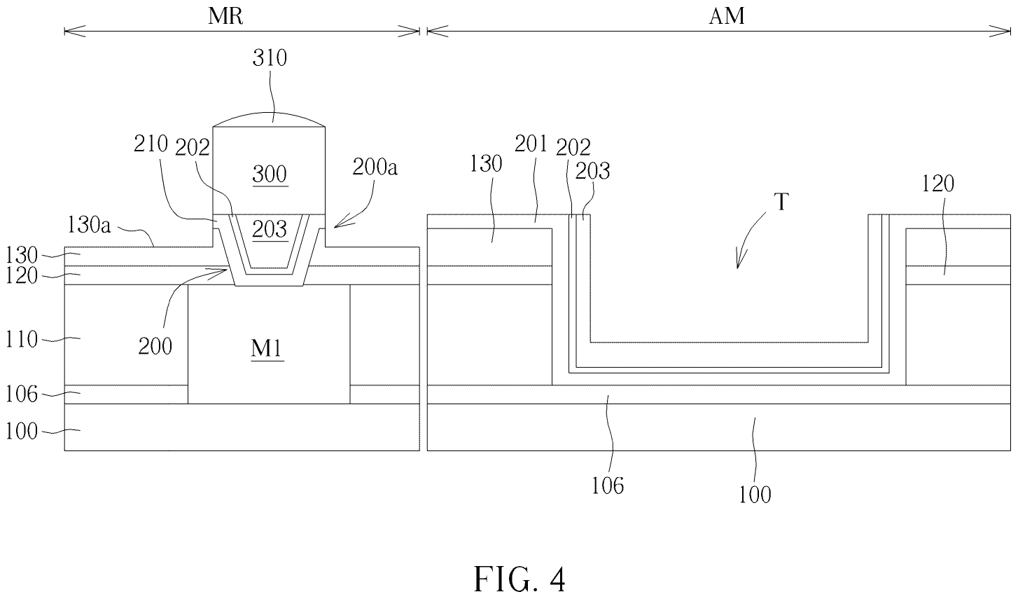

As shown in FIG. 4, a deposition process, a photolithography process and an etching process are then performed to form a resistive switching structure 300 on the conductive via 200 in the memory cell region MR. During the process of forming the resistive switching structure 300, the polishing stop layer 201 and part of the intermediate dielectric layer 130 that are not covered by the resistive switching structure 300 will be etched away. At this point, the conductive via 200 may include an upper portion 200a protruding from the top surface 130a of the intermediate dielectric layer 130, and the remaining thickness of the intermediate dielectric layer 130 is approximately 100 angstroms.

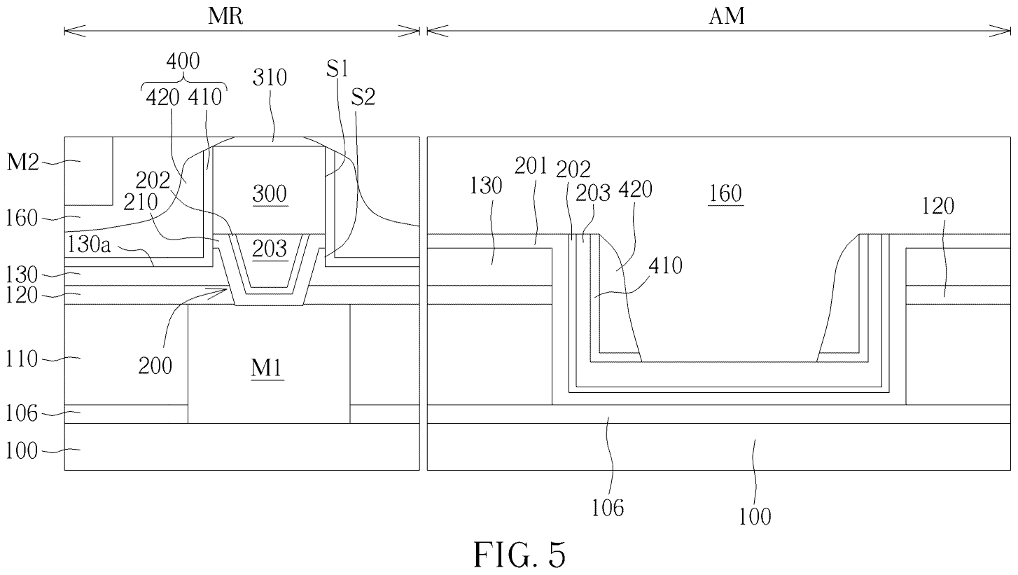

As shown in FIG. 5, a chemical vapor deposition (CVD) process and an etching process are then performed to form sidewall spacer 400 around the upper portion 200a of the conductive via 200 and the resistive switching structure 300. According to an embodiment of the present invention, for example, the sidewall spacer 400 may include a silicon nitride layer 410 and a silicon oxide layer 420, but is not limited thereto. According to an embodiment of the present invention, the silicon nitride layer 410 conformally covers the sidewall S1 of the resistive switching structure 300, the sidewall S2 of the upper portion 200a of the conductive via 200, and the top surface 130a of the intermediate dielectric layer 130. According to an embodiment of the present invention, the silicon nitride layer 410 directly contacts the polishing stop layer 201, but does not directly contact the barrier layer 202 and the tungsten layer 203. According to an embodiment of the present invention, a second interlayer dielectric layer 160 is then formed on the sidewall spacer 400 and the resistive switching structure 300. Subsequently, the metallization process may be continued to form the second interconnect structure M2 in the second interlayer dielectric layer 160.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A resistive random access memory device, comprising:
a substrate;
a first inter-layer dielectric (ILD) layer disposed on the substrate;
a first interconnect structure disposed in the first ILD layer;
a capping layer disposed on the first interconnect structure and the first ILD layer;
an intermediate dielectric layer disposed on the capping layer;
a conductive via disposed in the capping layer and the intermediate dielectric layer, wherein the conductive via comprises a polishing stop layer, a barrier layer on the polishing stop layer, and a tungsten layer on the barrier layer; and
a resistive switching structure disposed on the conductive via.

2. The resistive random access memory device according to claim 1, wherein the conductive via comprises an upper portion protruding from a top surface of the intermediate dielectric layer.

3. The resistive random access memory device according to claim 2 further comprising:
a sidewall spacer disposed around the upper portion of the conductive via and the resistive switching structure.

4. The resistive random access memory device according to claim 3, wherein the sidewall spacer covers a sidewall of the resistive switching structure, a sidewall of the upper portion of the conductive via, and the top surface of the intermediate dielectric layer, and wherein the sidewall spacer is in direct contact with the polishing stop layer.

5. The resistive random access memory device according to claim 3, wherein the sidewall spacer layer comprises a silicon nitride layer and a silicon oxide layer.

6. The resistive random access memory device according to claim 1, wherein the capping layer comprises a nitrogen-doped silicon carbide (NDC) layer.

7. The resistive random access memory device according to claim 1, wherein the intermediate dielectric layer comprises a TEOS-based silicon oxide layer.

8. The resistive random access memory device according to claim 1, wherein the polishing stop layer comprises tantalum nitride.

9. The resistive random access memory device according to claim 1, wherein the barrier layer comprises titanium nitride.

10. The resistive random access memory device according to claim 3 further comprising:
a second inter-layer dielectric (ILD) layer covering the sidewall spacer; and
a second interconnect structure disposed in the second ILD layer.

11. A method for forming a resistive random access memory device, comprising:
providing a substrate;
forming a first inter-layer dielectric (ILD) layer on the substrate;
forming a first interconnect structure in the first ILD layer;
forming a capping layer on the first interconnect structure and the first ILD layer;
forming an intermediate dielectric layer on the capping layer;
forming a conductive via in the capping layer and the intermediate dielectric layer, wherein the conductive via comprises a polishing stop layer, a barrier layer on the polishing stop layer, and a tungsten layer on the barrier layer; and
forming a resistive switching structure on the conductive via.

12. The method according to claim 11, wherein the conductive via comprises an upper portion protruding from a top surface of the intermediate dielectric layer.

13. The method according to claim 12 further comprising:
forming a sidewall spacer around the upper portion of the conductive via and the resistive switching structure.

14. The method according to claim 13, wherein the sidewall spacer covers a sidewall of the resistive switching structure, a sidewall of the upper portion of the conductive via, and the top surface of the intermediate dielectric layer, and wherein the sidewall spacer is in direct contact with the polishing stop layer.

15. The method according to claim 13, wherein the sidewall spacer layer comprises a silicon nitride layer and a silicon oxide layer.

16. The method according to claim 11, wherein the capping layer comprises a nitrogen-doped silicon carbide (NDC) layer.

17. The method according to claim 11, wherein the intermediate dielectric layer comprises a TEOS-based silicon oxide layer.

18. The method according to claim 11, wherein the polishing stop layer comprises tantalum nitride.

19. The method according to claim 11, wherein the barrier layer comprises titanium nitride.

20. The method according to claim 13 further comprising:
forming a second inter-layer dielectric (ILD) layer on the sidewall spacer; and
forming a second interconnect structure in the second ILD layer.
